(19) United States
(12) Patent Application Publication
(10) Pub. No.: US 2018/0287709 A1
(43) Pub. Date: Oct. 4, 2018

(54) OPTICAL COMMUNICATION TRANSMITTER

(71) Applicant: National Taipei University of Technology, Taipei (TW)

(72) Inventors: Hai-Han Lu, Taipei (TW); Chung-Yi Li, Taipei (TW)

(21) Appl. No.: 15/617,747

(22) Filed: Jun. 8, 2017

(30) Foreign Application Priority Data
Mar. 28, 2017 (TW) 106110398

(51) Int. Cl. H04B 10/54; H04B 10/2581; H04L 27/04; H04B 10/50; H01S 5/183; H01S 5/042; H01S 5/40; H01S 5/0683; H01S 5/022

(52) U.S. Cl. CPC H04B 10/541; H04B 10/2581; H04L 27/04; H04B 10/5057; H01S 5/02284; H01S 5/0427; H01S 5/4006; H01S 5/0683; H01S 5/183

(57) ABSTRACT

An optical communication transmitter includes a modulation circuit and a vertical cavity surface emitting laser (VCSEL) transmission module, The modulation circuit is used for performing a four-level pulse amplitude modulation (PAM4) on the input data in order to generate a modulation signal. The VCSEL transmission module is coupled to the modulation circuit and uses an injection lock technique to generate and transmit an output optical signal based on the modulation signal.

### BACKGROUND OF THE INVENTION

### Field of the Invention

The present invention is related to an optical communication technology, in particular, to an optical transmitter having excellent frequency response characteristic and bit error rate.

### Description of Related Art

Optical communication refers to a method of transmitting information via light and optical fiber. In addition, optical communication is known to have numerous merits of great transmission capacity and excellent data confidentiality. In an optical communication system, information to be transmitted is inputted into the transmitter from the transmission end, and the information is stacked or modulated onto the optical carrier used as the information signal carrier, following which the modulated optical carrier is transmitted to the reception end at a remote location via a transmission medium. Subsequently, the receiver then performs demodulation to obtain the original information.

As the development of the optical communication becomes mature, the demand for higher data transmission rate and bandwidth of optical communication systems also increases. Currently, a great number of scholars and developers endeavor to research and develop a data transmission format that is capable of satisfying the data transmission rate and the requirements for bandwidth at the same time.

### SUMMARY OF THE INVENTION

The present invention provides an optical communication transmitter having the characteristics of high data transmission and high frequency bandwidth.

According to an embodiment of the present invention, an optical communication transmitter comprises a modulation circuit and a vertical cavity surface emitting laser (VCSEL) transmission module. The modulation circuit is configured to perform a four-level pulse amplitude modulation (PAM4) on an input data in order to generate a modulation signal. The VCSEL transmission module is coupled to the modulation circuit and is configured to use an injection lock technique in order to generate and transmit an output optical signal based on the modulation signal.

Based on the above, according to an embodiment of the present invention, an optical communication transmitter is able to utilize the PAM4 modulation along with the injection lock technique and the opto-electronic feedback technology in order to obtain a transmission optical wave with relatively better frequency response characteristic and bit error rate as the transmission signal such that the optical communication system of the optical communication transmitter according to a preferred embodiment of the present invention can have a relatively greater data transmission rate.

To facilitate the illustration of the aforementioned technical features and advantages of the present invention, the following provides a detailed description on embodiments of the present invention along with the accompanied drawings.

### BRIEF DESCRIPTION OF DRAWING

FIG. 1 is a schematic view of a system structure of the optical communication transmitter according to an embodiment of the present invention;

FIG. 2 is a schematic view showing the signal formats of the NRZ signal and PAM4 signal according to an embodiment of the present invention;

FIG. 3 is a schematic view of a structure of the injection lock circuit according to an embodiment of the present invention; and

FIG. 4 is a schematic view of a structure of the opto-electronic feedback circuit according to an embodiment of the present invention.

### DETAILED DESCRIPTION OF THE INVENTION

To facilitate the understanding of the content disclosed in the present application, the following provides examples of embodiments of the present invention capable of being implemented in practice. In addition, in the accompanied drawings and embodiments, elements/part/steps labeled with identical signs and symbols shall refer to identical or similar parts.

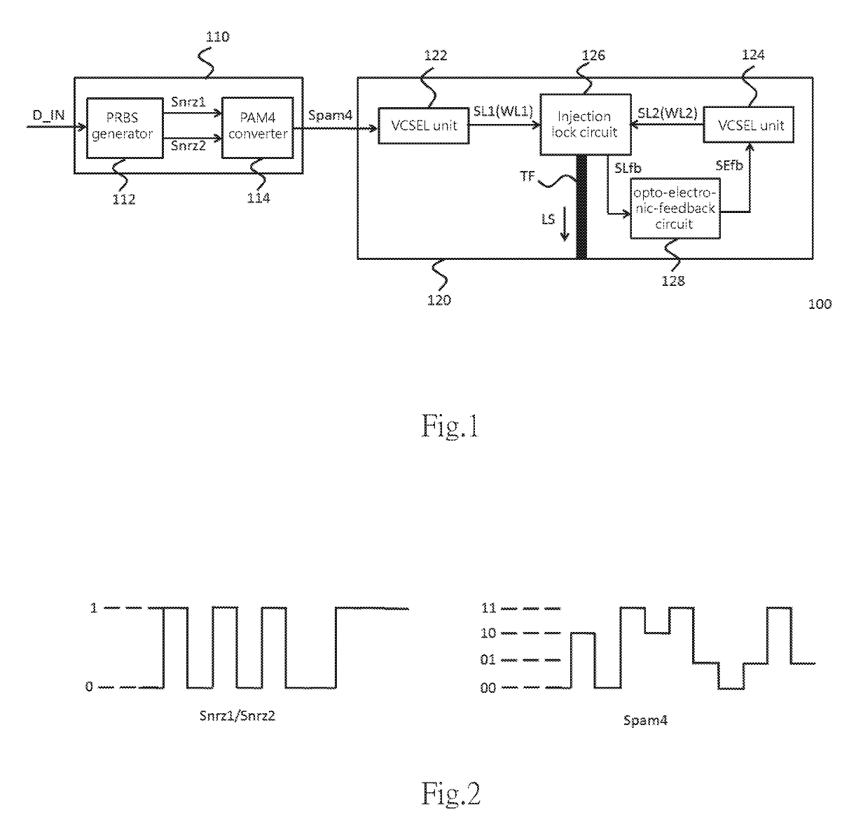

FIG. 1 shows a schematic view of a system structure of an optical communication transmitter according to an embodiment of the present invention. As shown in FIG. 1, an optical communication transmitter 100 is configured to receive an input data D_IN (such as: encoded data) and to perform a modulation on the input data D_IN, followed by generating an output optical signal LS for emitting into the environment based on the modulated input data D_IN. In other words, the input data D_IN can undergo modulation in order to use optical wave as the carrier, and the modulated input data D_IN can be carried on the carrier in order to form the output optical signal LS.

In a specific application, the optical communication transmitter 100 can correspond to an optical receiver (not shown in the drawings) to form an optical communication system. The optical receiver can be used for receiving the optical wave collected from the environment and converting the output optical signal LS into an electrical signal, following which after signal processes of amplification and equalization etc. are performed on the electrical signal, modulation can be further performed on the electrical signal processed in order to generate output data corresponding to the input data D_IN.

In this embodiment, the optical communication transmitter 100 and the optical communication system using such transmitter can be used in applications of indoor multi-point positioning, message broadcasting, remote detection application services and underwater communication application etc. Preferably, the optical communication transmitter 100 in this embodiment is applied to the signal transmission of wired optical communication/optical fiber communication; however, the present invention is not limited to such applications only.

Specifically, the optical communication transmitter 100 comprises a modulation circuit 110 and a vertical cavity surface emitting laser (VCSEL) transmission module 120. The modulation circuit 110 is configured to perform a four-level pulse amplitude modulation (PAM4) on the input data D_IN in order to generate a modulation signal Spam4.

The VCSEL transmission module 120 is coupled to the modulation circuit 110 and is able to generate the corresponding output optical signal LS based on the modulation signal Spam4 received; in other words, it is able to convert the electrical signal into the form of an optical wave. In this embodiment, the VCSEL transmission module 120 is able to use the injection lock technique in order to generate and transmit the output optical signal LS based on the modulation signal Spam4. To be more specific, during the use of the injection lock technique, the VCSEL transmission module 120 is able to generate an optical signal based on the modulation signal, and the optical signal is fed back and converted into an electrical signal, which is also used as a reference for generating another optical signal. In addition, the injection lock technique is performed on the two optical signals in order to generate the output optical signal LS. The output optical signal LS carries the information of the modulation signal Spam4; furthermore, due to the effect of the injection lock technique, it exhibits the mode-lock characteristic such that it can allow the wavelength of the signal to be maintained at a particular wavelength.

In terms of the operation of the transmitter, the data to be transmitted is loaded onto the modulation circuit 110 after encoding, and the PAM4 technique is used to convert it into a current or voltage varying along with the signal in order to drive the light source in the VCSEL transmission module 120; in other words, the electrical signal is converted into the output optical signal LS. Next, the VCSEL transmission module 120 is able to use a wired/wireless optical transmission technique to transmit the output optical signal LS in a channel via optical fibers or lenses. Moreover, for the reception end, the optical receiver is able to gather the light beams transmitted via the optical reception technique of optical fibers or lenses etc. onto a photodetector. Then, the photodetector is able to convert the optical signal received into an electrical signal, following which signal processing is performed by the signal processing module of the optical receiver. Finally, a demodulation circuit is able to demodulate the signal into the original message.

In another exemplary embodiment, the optical communication transmitter 100 further comprises a multimode fiber TF. The multimode fiber TF is connected to the output end of the VCSEL transmission module 120 and is configured to transmit the output optical signal LS. In an actual application, the multimode fiber TF can be, for example, an OM4 optical fiber. The center radius of the 0M4 optical fiber can be, for example, 50±2.5 μm, and the bending loss can be, for example, 0.5 dB (100 turns, curvature of radius 75 mm). In addition, the transmission length of the multimode fiber TF can be set to be between 0 m and 250 m; preferably, the multimode fiber TF is set to be less than 209 m; and a preferred bit error rate (BER) characteristic can be measured at this time.

In an embodiment, the modulation circuit 110 comprises a pseudorandomness binary sequence (PRBS) generator 112 and a PAM4 converter 114. The PRBS generator 112 is configured to receive the input data D_IN and to convert the input data D_IN into a plurality of non-return-zero signals (NRZ signals) with a binary data stream format. Here, the non-return-zero signals Snrz1 and Snrz2 are used as examples for illustration. The PAM4 converter 114 is coupled to the PRBS generator 112. The PAM4 converter 114 is configured to use a PAM4 modulation technique to convert the non-return-zero signals Snrz1 and Snrz2 into the modulation signal Spam4 with the PAM4 format.

FIG. 2 shows a schematic view of the signal formats of the NRZ signal and the PAM 4 signal according to an embodiment of the present invention. As shown in FIG. 2, in the signal formats of the non-zero-return signals Snrz1 and Snrz2, each pulse has only two data coding levels, i.e. 0 and 1. When the two non-return-zero signals Snrz1 and Snrz2 are modulated via PAM4, each pulse then has four data coding levels, i.e. 00, 01, 10 and 11. In other words, after the conversion of the non-zero-return signals Snrz1 and Snrz2 are converted via PAM4, they are of higher information carrying capacity, meaning that they are of higher data transmission rate.

In an actual application, the transmission rate of the non-return-zero signals Snrz1 and Snrz2 generated by the PRBS generator 112 is, for example, 22.5 Gb/s. In addition, for the modulation signal Spam4 generated after the non-return-zero signals Snrz1 and Snrz2 converted by the PAM4 converter, its transmission rate can reach 45 Gb/s. However, it can be understood that the present invention is not limited to such values only. Moreover, in this embodiment, the two non-return-zero signals Snrz1 and Snrz2 can have different signal amplitudes, such as, 900 mV and 450 mV respectively; however, the present invention is, again, not limited to such values only.

Please refer to FIG. 1. In this embodiment, the VCSEL transmission module 120 comprises two VCSEL units 122 and 124, an injection lock circuit 126 and an opto-electronic feedback circuit 128. The VCSEL unit 122 is coupled to the PAM4 converter 114 of the modulation circuit 110 and is configured to excite and emit an optical signal SL1 having a wavelength WL1 based on the modulation signal Spam4. The VCSEL unit 124 is configured to excite and emit an optical signal SL2 having a wavelength WL2. The injection lock circuit 126 is coupled to the VCSEL units 122 and 124, which is configured to couple the optical signals SL1 and SL2 together in order to generate an output optical signal SLi having the mode-lock characteristic. The opto-electronic feedback circuit 128 is coupled to the VCSE1 unit 124 and the injection lock circuit 126. The opto-electronic feedback circuit 128 can be used to generate a feedback electrical signal SEfb based on the output optical signal LS, and it is able to transmit the feedback electrical signal SEfb to the VCSEL unit 124. The VCSEL unit 124 excites and emits the optical signal SL2 based on the feedback electrical signal SEfb.

Specifically, with the use of the injection lock technique and the opto-electronic feedback technology for generating the output optical signal, the output optical signal LS generated by the optical communication transmitter 100 in this embodiment is able to have a relatively better frequency response characteristic. According to the verification of data via experiments, for a VCSEL transmission module 120 with the use of VCSEL and injection lock technique along with the opto-electronic feedback technology, the 3 dB bandwidth of its output optical signal can reach 21.5 GHz. In comparison to a conventional VCSEL, the frequency response characteristic of the VCSEL transmission module 120 in this embodiment of the present invention outperforms the traditional VCSEL by a factor of 2.9 times greater.

To be more specific, in the VCSEL transmission module 120, the VCSEL unit 122 can be deemed as a primary laser, and the VCSEL unit 124 can be deemed as a secondary laser. There is a little amount of wavelength shift (such as 0.03 nm) between the signals transmitted by the primary laser and the secondary laser such that when the primary laser and the secondary laser are coupled with each other, the phenomena of injection lock occurs; consequently, the output optical signal LS outputted is of the mode-lock characteristic. Furthermore, preferably, the injection lock effect occurs in the situation where the primary laser frequency is slightly lower than the secondary laser frequency. In this embodiment, the VCSEL units 122 and 124 can be designed to have the same optical characteristics.

In an actual application, the wavelength WL1 of the VCSEL unit 122 is, for example, between 851.84 nm and 852.12 nm; in addition, the wavelength of the VCSEL unit 124 is, for example, between 851.81 nm and 852.09 nm. However, it can be understood that the present invention is not limited to such values only.

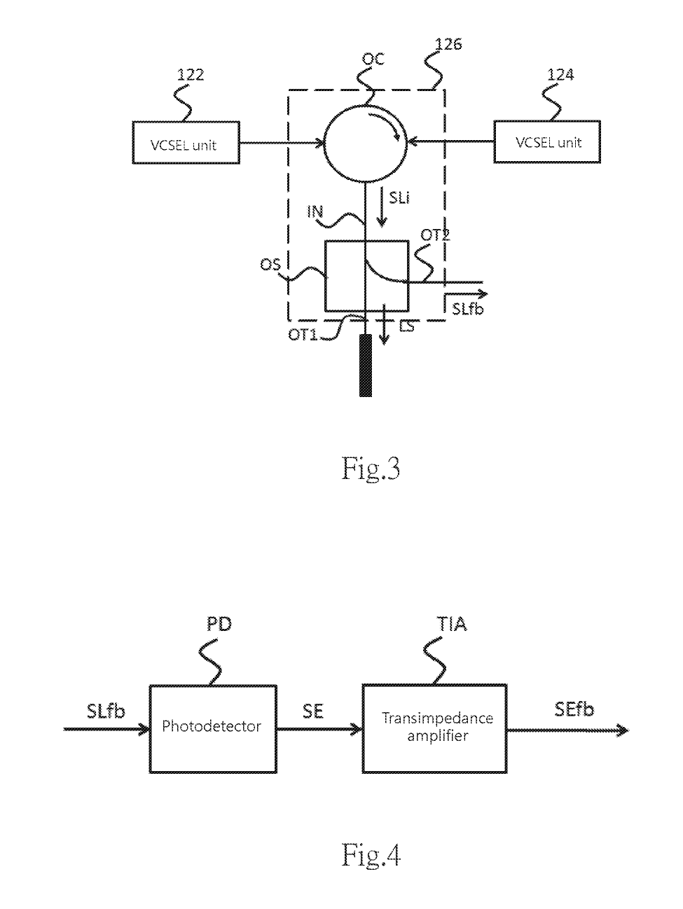

FIG. 3 shows a schematic view of a structure of the injection lock circuit according to an embodiment of the present invention. A shown in FIG. 3, the injection lock circuit 126 comprises an optical circulator OC and an optical splitter OS. The optical circulator OC is coupled to the VCSEL unit 122 and the VCSEL unit 124. The optical circulator OC is configured to guide the optical transmission directions of the optical signals SL1 and SL2 in order to provide an injection path for coupling the optical signals SL1 and SL2 with each other and to generate the mode-lock signal SLi accordingly. In this embodiment, the operating wavelength of the optical circulator 126 can be, for example, 850 nm; however, the present invention is not limited to such value only.

The optical splitter OS can be, for example, a 1×2 optical splitter having an input end IN and output ends OT1 and OT2. The input end IN of the optical splitter OS is coupled to the output end of the optical circulator OC in order to receive the mode-lock optical signal SLi. The optical splitter OS is able to split the mode-lock optical signal SLi into an output optical signal LS and a feedback optical signal SLfb. The output optical signal LS can be outputted via the output end OT1 and can be provided to the multimode fiber TF. The feedback optical signal SLfb can be outputted via the output end OT2 and can be provided to the opto-electronic feedback circuit 128.

FIG. 4 shows a schematic view of a structure of the opto-electronic feedback circuit according to an embodiment of the present invention. Please refer to FIG. 1, FIG. 3 and FIG. 4. In this embodiment, the opto-electronic feedback circuit 128 comprises a photodetector PD and a transimpedance amplifier TIA. The photodetector PD is coupled to the output end OT2 of the optical splitter OS in order to receive the feedback optical signal SLfb, wherein the photodetector PD is able to convert the feedback optical signal SLfb into an electrical signal SE. The transimpedance amplifier TIA is coupled to the photodetector PD and is configured to convert the electrical signal SE in a current form into a feedback electrical signal SEfb in a voltage form as well as to transmit the feedback electrical signal SEfb to the VCSEL unit 124 as the basis for generating the optical signal SL2.

In view of the above, the embodiments of the present invention provides an optical communication transmitter capable of using the PAM4 modulation along with the injection lock technique and opto-electronic feedback technology in order to obtain an emission of optical wave having relatively better frequency response characteristic and bit error rate for transmission signal; therefore, an optical communication system with the use of the optical communication transmitter according to the embodiment of the present invention therein can have a relatively greater data transmission rate.

It can be understood that although the present invention has been illustrated with preferred embodiments as disclosed above, such embodiments shall not be used to limit the present invention. Any person skilled in the art in this field is able to make modifications and refinements without deviating the spirit and scope of the present invention. Therefore, the scope of the present invention shall be based on the claims recited hereafter.

What is claimed is:

1. An optical communication transmitter, comprising:
a modulation circuit configured to perform a four-level pulse amplitude modulation (PAM4) on an input data in order to generate a modulation signal; and
a vertical cavity surface emitting laser transmission module coupled to the modulation circuit and configured to use an injection lock technique in order to generate and transmit an output optical signal based on the modulation signal

2. The optical communication transmitter according to claim 1, wherein the modulation circuit comprises:
a pseudorandomness binary sequence (PRBS) generator configured to receive the input data and to convert the input data into a plurality of non-return-zero signals (NRZ signals) with a binary data stream format; and
a four-level pulse amplitude modulation converter coupled to the pseudorandomness binary sequence generator in order to use a four-level pulse amplitude modulation to convert the plurality of non-return-to-zero signals into the modulation signal.

3. The optical communication transmitter according to claim 2, wherein the plurality of non-return-to-zero signals are of a transmission rate of 22.5 Gb/s, and the modulation signal is of a transmission rate of 45 Gb/s.

4. The optical communication transmitter according to claim 2, wherein one of the plurality of non-return-to-zero signals is of an amplitude of 900 mV, and another one of the plurality of non-return-to-zero signals is of an amplitude of 450 mV.

5. The optical communication transmitter according to claim 1, wherein the vertical cavity surface emitting laser transmission module comprises:
a first vertical cavity surface emitting laser unit coupled to the modulation circuit and configured to excite and emit a first optical signal having a first wavelength based on the modulation signal;
a second vertical cavity surface emitting laser unit configured to excite and emit a second optical signal having a second wavelength;
an injection lock circuit coupled to the first vertical cavity surface emitting laser unit and the second vertical cavity surface emitting laser unit as well as configured to couple the first optical signal with the second optical signal in order to generate the output optical signal having a mode-lock characteristic; and
an opto-electronic feedback circuit coupled to the second vertical cavity surface emitting laser unit and the injection lock circuit as well as configured to generate a feedback electrical signal based on the output optical signal and to transmit the feedback electrical signal to the second vertical cavity surface emitting laser unit; and
wherein the second vertical cavity surface emitting laser unit excites and emits the second optical signal based on the feedback electrical signal.

6. The optical communication transmitter according to claim 5, wherein the first wavelength is between 851.84 nm and 852.12 nm, and the second wavelength is between 851.81 nm and 852.09 nm.

7. The optical communication transmitter according to claim 5, wherein the injection lock circuit comprises:
an optical circulator coupled to the first vertical cavity surface emitting laser unit and the second vertical cavity surface emitting laser unit as well as configured to guide optical transmission directions of the first optical signal and the second optical signal in order to provide an injection path for coupling the first optical signal with the second optical signal and to generate a mode-lock optical signal accordingly; and
an optical slipper having an input end, a first output end and a second output end; the input end coupled to the optical circulator; wherein the optical splitter is configured to split the mode-lock optical signal received into the output optical signal and a feedback optical signal; the first output end outputs the output optical signal and the second output end outputs the feedback optical signal.

8. The optical communication transmitter according to claim 7, wherein the opto-electronic feedback circuit comprises:
a photodetector coupled to the second output end of the optical splitter and configured to receive the feedback optical signal; wherein the photodetector converts the feedback optical signal into an electrical signal; and
a transimpedance amplifier coupled to the photodetector and configured to convert the electrical signal into the feedback electrical signal.

9. The optical communication transmitter according to claim 7, further comprising:
a multimode fiber coupled to the first output end of the optical splitter and configured to transmit the output optical signal.

10. The optical communication transmitter according to claim 9, wherein the multimode fiber is of a transmission length less than 250 m.

11. The optical communication transmitter according to claim 10, wherein the multimode fiber is of a transmission length greater than 200 m.

12. The optical communication transmitter according to claim 9, wherein the multimode fiber is an OM4 optical fiber.
